(19) United States
(12) Patent Application Publication
(10) Pub. No.: US 2004/0036098 A1
(43) Pub. Date: Feb. 26, 2004

(54) Semiconductor device including a capacitor

(75) Inventors: Noriaki Fujiki, Tokyo (JP); Takao Kamoshima, Tokyo (JP); Hiroki Takewaka, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/366,405

(22) Filed: Feb. 14, 2003

(30) Foreign Application Priority Data
Aug. 22, 2002 (JP) 2002-241317

(51) Int. Cl. H01L 27/108; H01L 29/76; H01L 29/94; H01L 31/119

(52) U.S. Cl. 257/296

(57) ABSTRACT

The upper surface of a second interlayer insulating film (3) and the upper surface of a first interconnect line (11) made of copper are different in height. Therefore, in the upper surface of a three-layered film provided thereon for constituting an MIM capacitor (13), difference in level is generated at the position corresponding to that of the first interconnect line (11). During patterning of this three-layered film, it is possible to optically detect the position of the difference, whereby the position of the first interconnect line (11) can be detected. As a result, alignment between the MIM capacitor (13) and the first interconnect line (11) can be precisely performed.

### BACKGROUND OF THE INVENTION

1. Field of the Invention

The present invention relates to a semiconductor device including a capacitor that uses an interconnect line as an electrode thereof.

2. Description of the Background Art

In a semiconductor device manufactured with design rules of quarter-micron level or less, increasing importance has been given to shrinkage of an interconnect structure and reduction in line resistance for suppressing signal delay. For compatibility therebetween, copper (Cu) has been widely used instead of aluminum (Al) as a material for a metal interconnect line.

As a semiconductor device expands in functionality, it is desired to add an MIM (metal insulator metal) capacitor to an interconnection. FIG. 21 is a view illustrating the exemplary structure of a background-art semiconductor device including an MIM capacitor. For convenience of illustration, the interconnect structure including an MIM capacitor provided between interconnect lines, and the conventional interconnect structure for connecting interconnect lines through a contact hole, are both shown.

The semiconductor structure illustrated in FIG. 21 has a first interlayer insulating film 2 provided on a silicon substrate 1. Provided on the first interlayer insulating film 2 is a second interlayer insulating film 3. The second interlayer insulating film 3 includes first interconnect layers 11 and 101, both of which are made of copper. A third interlayer insulating film 4 is provided on the second interlayer insulating film 3. Contact holes are defined in the third interlayer insulating film 4 and filled with aluminum deposited therein. Aluminum is further deposited on the third interlayer insulating film 4 for forming second interconnect lines 12 and 102. An MIM capacitor 13 is provided on the first interconnect line 11. The second interconnect line 12 provided over the MIM capacitor 13 is connected to the MIM capacitor 13 through the contact hole. That is, the first interconnect line 11 serves as a lower electrode, and the second interconnect line 12 serves as an upper electrode of the MIM capacitor 13. The second interconnect line 102 is connected to the first interconnect line 101 through the contact hole defined in the third interlayer insulating film 4. Namely, in FIG. 1, the left half of the structure shows interconnection including the MIM capacitor 13 provided between the first interconnect line 11 and the second interconnect line 12, and the right half of the structure shows conventional interconnection for connecting the first interconnect line 101 and the second interconnect line 102 through the contact hole. A passivation film 5 is provided on the third interlayer insulating film 4, and on the second interconnect lines 12 and 102.

The steps of manufacturing the background-art semiconductor device illustrated in FIG. 21 will be described. First, the first interlayer insulating film 2, the second interlayer insulating film 3, and the first interconnect lines 11 and 101 made of copper are provided over the silicon substrate 1. In contrast to aluminum, dry etching of copper is difficult. In view of this, when the first interconnect lines 11 and 101 are to be formed using copper, a damascene process is generally employed. More particularly, the first interlayer insulating film 2 and the second interlayer insulating film 3 are formed by the combination of processes including CVD, etchback, CMP and the like. Thereafter trenches for forming the first interconnect lines 11 and 101 are defined in the second interlayer insulating film 3 by photolithography and dry etching. Next, a TaN or TiN film to serve as a barrier against copper diffusion (copper diffusion preventing film) is deposited by sputtering, followed by plating or CVD for filling the trenches with copper. Then the excess copper and the barrier film on the upper surface of the second interlayer insulating film 3 are removed by polishing using CMP, whereby the first interconnect lines 11 and 101 are formed in the trenches. The upper surfaces of the resultant first interconnect lines 11 and 101, and of the second interlayer insulating film 3 are flat, namely, they each have a constant height. Further, the upper surfaces of the first interconnect lines 11 and 101, and of the second interlayer insulating film 3 are the same in height.

Next, using sputtering or CVD, a three-layered film for constituting the MIM capacitor 13 is deposited on the upper surfaces of the first interconnect lines 11 and 101, and of the second interlayer insulating film 3. This three-layered film generally includes a dielectric film 13b, and high melting point metal films 13a and 13c holding therebetween the dielectric film 13b. The exemplary material is TiN or TaN for the high melting point metal films 13a and 13c, and SiO, SiN, or SiON for the dielectric film 13b. FIG. 22 illustrates the structure in which the high melting point metal films 13a and 13c, and the dielectric film 13b (hereinafter referred to as “three-layered film”) for constituting the MIM capacitor 13 are provided on the upper surfaces of the first interconnect lines 11 and 101, and of the second interlayer insulating film 3. As the upper surfaces of the first interconnect lines 11 and 101, and of the second interlayer insulating film 3 are flat and have the same height as described, the upper surface of the three-layered film provided thereon is also flat.

The three-layered film is then patterned, to form the MIM capacitor 13 on the first interconnect line 11.

Thereafter, the third interlayer insulating film 4 is formed by the combination of processes including CVD, etchback, CMP and the like. Then contact holes are defined over the first interconnect line 11 (over the MIM capacitor 13) and over the first interconnect line 101. An aluminum film is thereafter deposited in the contact holes and on the third interlayer insulating film 4, and is patterned. The second interconnect lines 12 and 102 are thereby formed. Last, the passivation film 5 is provided to cover the third interlayer insulating film 4, and the second interconnect lines 12 and 102.

According to the description given with reference to FIG. 21, the second interconnect lines 12 and 102 are shown to be aluminum lines. Similar to the first interconnect lines, they may alternatively be copper lines. FIG. 23 illustrates the structure in which the second interconnect lines are made of copper. In contrast to aluminum, copper is hard-to-etch metal as described. In view of this, the damascene process is also employed for forming second interconnect lines 12a and 102a using copper. More particularly, after formation of the third interlayer insulating film 4, contact holes are defined therein. Following this, trenches for forming the second interconnect lines 12a and 102a are defined therein. Next, a barrier film against copper is deposited, and thereafter, the contact holes and the trenches are filled with copper. Then the excess copper and the barrier film on the upper surface of the third interlayer insulating film 4 are removed, whereby the second interconnect lines 12a and 102a are formed. Such process for sequentially defining a contact hole and an interconnect trench, and simultaneously filling them with an interconnect material, is called as a dual damascene process. Namely, in the dual damascene process, contact and interconnection can be formed at the same time.

Patterning of the three-layered film for forming the MIM capacitor 13 should be such that the resultant MIM capacitor 13 is exactly on the first interconnect line 11. That is, precise alignment between the MIM capacitor 13 and the first interconnect line 11 is required. It is thus necessary to optically detect the position of the first interconnect line 11 during lithography process for patterning. However, the high melting point metal films 13a and 13c do not allow light to pass therethrough. Further, following the foregoing background-art technique, the upper surface of the three-layered film becomes flat. For these reasons, the position of the first interconnect line 11 cannot be optically detected, causing the difficultly of precise alignment between the MIM capacitor 13 and the first interconnect line 11.

When alignment between the MIM capacitor 13 and the first interconnect line 11 is not done precisely and misalignment of the MIM capacitor 13 with the first interconnect line 11 is caused, the problem such as increase in leakage current at the edge portion of the MIM capacitor 13 may occur. As a result, characteristic deterioration of the semiconductor device such as deterioration in operational reliability may be caused.

### SUMMARY OF THE INVENTION

It is therefore an object of the present invention to provide a semiconductor device including a capacitor that uses a copper interconnect line as a lower electrode thereof, and a method of manufacturing the same. More particularly, it is the object of the present invention to perform precise alignment between the capacitor and the lower electrode.

According to a first aspect of the present invention, the semiconductor device includes an interlayer insulating film provided over a semiconductor substrate, an interconnect line provided in the interlayer insulating film, and a capacitor provided on the interconnect line. The interlayer insulating film has an upper surface at a constant height. The capacitor uses the interconnect line as a lower electrode thereof. The upper surfaces of the interconnect line and of the interlayer insulating film are different in height.

In the process for forming the capacitor that uses the interconnect line as a lower electrode thereof, the upper surface of a film for constituting the capacitor includes difference in level generated at the position corresponding to that of the interconnect line. During patterning of this film, it is possible to optically detect the position of the difference, whereby the position of the interconnect line is detected. Therefore, alignment between the capacitor and the interconnect line (lower electrode) can be precisely performed. As a result, in the semiconductor device, misalignment between the capacitor with the interconnect line is avoided, leading to improvement in reliability of the semiconductor device.

According to a second aspect of the present invention, the semiconductor device includes an interlayer insulating film provided over a semiconductor substrate, an interconnect line provided in the interlayer insulating film, and a capacitor provided on the interconnect line. The capacitor uses the interconnect line as a lower electrode thereof. A recessed portion is defined on the upper surface of the interconnect line.

In the process for forming the capacitor that uses the interconnect line as a lower electrode thereof, the upper surface of a film for constituting the capacitor to be provided on the interconnect line includes difference in level generated at the position corresponding to that of the interconnect line. During patterning of this film, it is possible to optically detect the position of the difference, whereby the position of the interconnect line is detected. Therefore, alignment between the capacitor and the interconnect line (lower electrode) can be precisely performed.

According to a third aspect of the present invention, the semiconductor device includes an interlayer insulating film provided over a semiconductor substrate, an interconnect line and an alignment mark provided in the interlayer insulating film, and a capacitor provided on the interconnect line. The interconnect line and the alignment mark are made of the same material. The capacitor uses the interconnect line as a lower electrode thereof. A recessed portion is defined on the upper surface of the alignment mark.

In the process for forming the capacitor that uses the interconnect line as a lower electrode thereof, the upper surface of a film for constituting a capacitor to be provided on the alignment mark includes difference in level generated at the position corresponding to that of the alignment mark. During patterning of this film, it is possible to optically detect the position of the difference, whereby the position of the alignment mark is detected. Therefore, alignment between the capacitor and the interconnect line (lower electrode) can be precisely performed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 illustrates the structure of a semiconductor device according to a first preferred embodiment of the present invention;

FIGS. 2 and 3 illustrate the steps of manufacturing the semiconductor device according to the first preferred embodiment of the present invention;

FIG. 4 illustrates the structure of a semiconductor device according to a modification of the first preferred embodiment of the present invention;

FIG. 5 illustrates the structure of a semiconductor device according to a second preferred embodiment of the present invention;

FIGS. 6 and 7 illustrate the steps of manufacturing the semiconductor device according to the second preferred embodiment of the present invention;

FIG. 8 illustrates the structure of a semiconductor device according to a modification of the second preferred embodiment of the present invention;

FIG. 9 illustrates the structure of a semiconductor device according to a third preferred embodiment of the present invention;

FIGS. 10 through 12 illustrate the steps of manufacturing the semiconductor device according to the third preferred embodiment of the present invention;

FIGS. 13 and 14 each illustrate the structure of a semiconductor device according to a modification of the third preferred embodiment of the present invention;

FIG. 15 illustrates the structure of a semiconductor device according to a fourth preferred embodiment of the present invention;

FIGS. 16 and 17 illustrate the steps of manufacturing the semiconductor device according to the fourth preferred embodiment of the present invention;

FIG. 18 illustrates the structure of a semiconductor device according to a modification of the fourth preferred embodiment of the present invention;

FIG. 19 illustrates the structure of a semiconductor device according to a fifth preferred embodiment of the present invention;

FIG. 20 illustrates the structure of a semiconductor device according to a modification of the fifth preferred embodiment of the present invention;

FIG. 21 illustrates the exemplary structure of the background-art semiconductor device including an MIM capacitor;

FIG. 22 shows the problem to be solved in the background-art semiconductor device; and

FIG. 23 illustrates the exemplary structure of the background-art semiconductor device including an MIM capacitor.

### DESCRIPTION OF THE PREFERRED EMBODIMENTS

First Preferred Embodiment

FIG. 1 illustrates the structure of a semiconductor device according to the first preferred embodiment of the present invention. In FIG. 1, the same device elements as those in FIG. 21 are designated by the same reference numerals. The first interconnect lines 11 and 101 are copper lines, and the second interconnect lines 12 and 102 are aluminum lines. Similar to FIG. 21, the left half of the structure in FIG. 1 shows interconnection including the MIM capacitor 13 provided between the first interconnect line 11 and the second interconnect line 12, and the right half thereof shows interconnection for connecting the first interconnect line 101 and the second interconnect line 102 through a contact hole.

As shown in FIG. 1, the upper surface of the second interlayer insulating film 3 has a constant height. Further, the upper surface of the first interconnect line 11 reaches a height greater than that of the second interlayer insulating film 3. That is, the upper surfaces of the first interconnect line 11 and the second interlayer insulating film 3 are different in height.

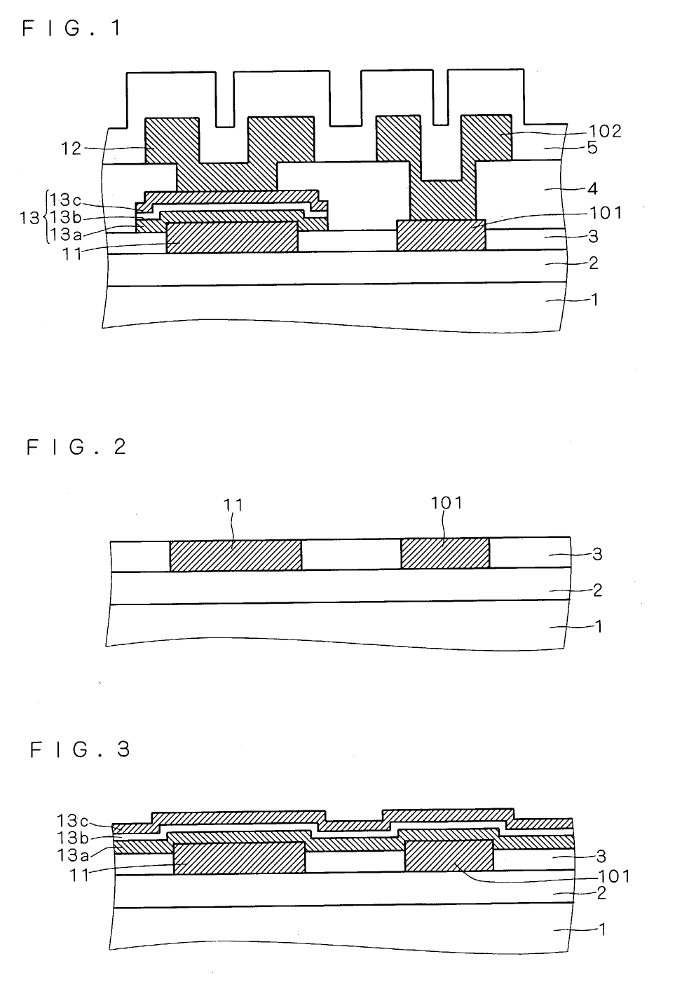

Next, the steps of manufacturing the semiconductor device according to the first preferred embodiment will be described. First, following the same manufacturing steps as those in the foregoing background art, the first interlayer insulating film 2, the second interlayer insulating film 3, and the first interconnect lines 11 and 101 are provided over the silicon substrate 1. As copper is used as a material for forming the first interconnect lines 11 and 101, the damascene process is employed. The upper surfaces of the resultant first interconnect lines 11 and 101, and of the second interlayer insulating film 3 are thus flat as shown in FIG. 2.

Etching selectivity can be defined between the first interconnect lines 11 and 101, and the second interlayer insulating film 3. Therefore, using the process such as dry etching for selectively etching the second interlayer insulating film 3, the upper surfaces of the first interconnect lines 11 and 101, and of the second interlayer insulating film 3 are etched, so that the second interlayer insulating film 3 is etched to a greater depth. As a result, the upper surface of the second interlayer insulating film 3 is lower in height than the first interconnect lines 11 and 101. Difference in height between the upper surfaces of second interlayer insulating film 3, and of the first interconnect lines 11 and 101, namely, difference in level therebetween, is preferably 50 nm or more.

Next, using sputtering or CVD, a three-layered film for constituting the MIM capacitor 13 (including the high melting point metal films 13a and 13c, and the dielectric film 13b) is deposited on the upper surfaces of the first interconnect lines 11 and 101, and of the second interlayer insulating film 3. More particularly, the high melting point metal film 13a, the dielectric film 13b, and the high melting point metal film 13c are deposited in this order. The upper surface of the second interlayer insulating film 3 has different height from those of the first interconnect lines 11 and 101. Therefore, the upper surface of the three-layered film provided thereon includes differences in level generated at the positions corresponding to those of the first interconnect lines 11 and 101 as shown in FIG. 3.

The three-layered film is then patterned by dry etching, to form the MIM capacitor 13 on the first interconnect line 11. During lithography process for this patterning, the positions of the differences in level of the three-layered film can be optically detected. As these differences are defined at the positions corresponding to those of the first interconnect lines 11 and 101, the positions of the differences can be used for detecting the position of the first interconnect line 11. It is thus possible to perform precise alignment between the MIM capacitor 13 and the first interconnect line 11.

As a result, the MIM capacitor 13 formed by patterning of the three-layered film can be precisely on the first interconnect line 11. That is, misalignment of the MIM capacitor 13 with the first interconnect line 11 is avoided, whereby characteristic deterioration of the semiconductor device such as deterioration in operational reliability may be suppressed.

Thereafter, following the same processes as those in the background art, the third interlayer insulating film 4 is provided, and contact holes are defined over the first interconnect line 11 (over the MIM capacitor 13) and over the first interconnect line 101. An aluminum film is then deposited in the contact holes and on the third interlayer insulating film 4, and is patterned. The second interconnect lines 12 and 102 are thereby formed. Last, the passivation film 5 is provided to cover the third interlayer insulating film 4, and the second interconnect lines 12 and 102. The resultant semiconductor device is as given in FIG. 1.

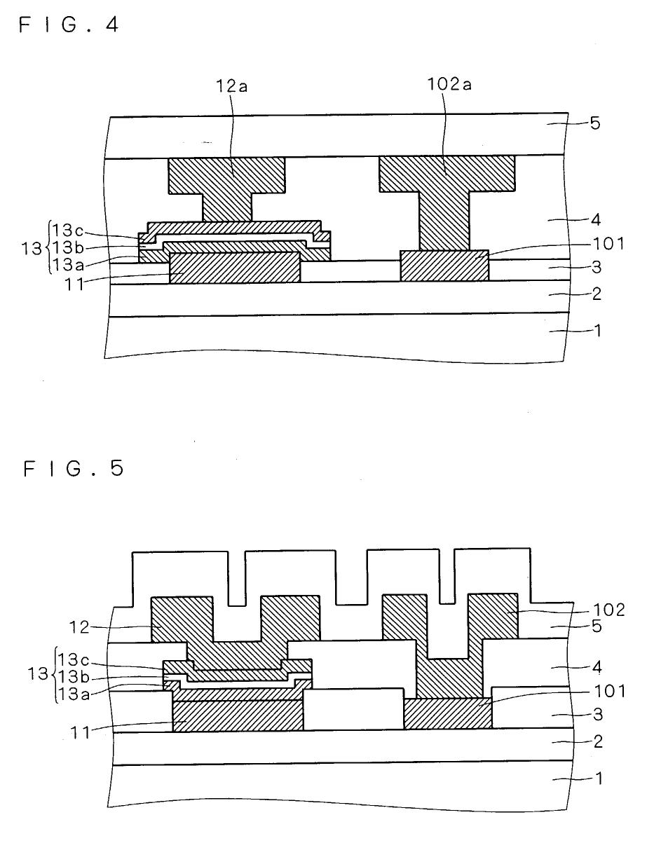

According to the foregoing description with reference to FIGS. 1 through 3, the second interconnect lines 12 and 102 are shown to be aluminum lines. Similar to the first interconnect lines, they may alternatively be copper lines. FIG. 4 illustrates the structure in which the second interconnect lines are made of copper. In contrast to aluminum, copper is hard-to-etch metal as described. In view of this, the damascene process is also employed for forming the second interconnect lines 12a and 102a using copper. More particularly, after formation of the third interlayer insulating film 4, contact holes are defined over the first interconnect line 11 (over the MIM capacitor 13) and over the first interconnect line 101. Following this, trenches for forming the second interconnect lines 12a and 102a are defined using the dual damascene process. Next, a barrier film against copper is deposited, and thereafter, the contact holes and the trenches are filled with copper. Then the excess copper and the barrier film on the upper surface of the third interlayer insulating film 4 are removed, whereby the second interconnect lines 12a and 102a are formed.

The process for forming the second interconnect lines 12a and 102a using copper is not limited to the dual damascene. Naturally, they may be formed by a single damascene process in which contact and interconnection are separately formed.

Second Preferred Embodiment

FIG. 5 illustrates the structure of a semiconductor device according to the second preferred embodiment of the present invention. In FIG. 5, the same device elements as those in FIG. 21 are designated by the same reference numerals. The first interconnect lines 11 and 101 are copper lines, and the second interconnect lines 12 and 102 are aluminum lines.

As shown in FIG. 5, the upper surface of the second interlayer insulating film 3 has a constant height. Further, the upper surface of the first interconnect line 11 is lower in height than the second interlayer insulating film 3. That is, the upper surfaces of the first interconnect line 11 and the second interlayer insulating film 3 are different in height.

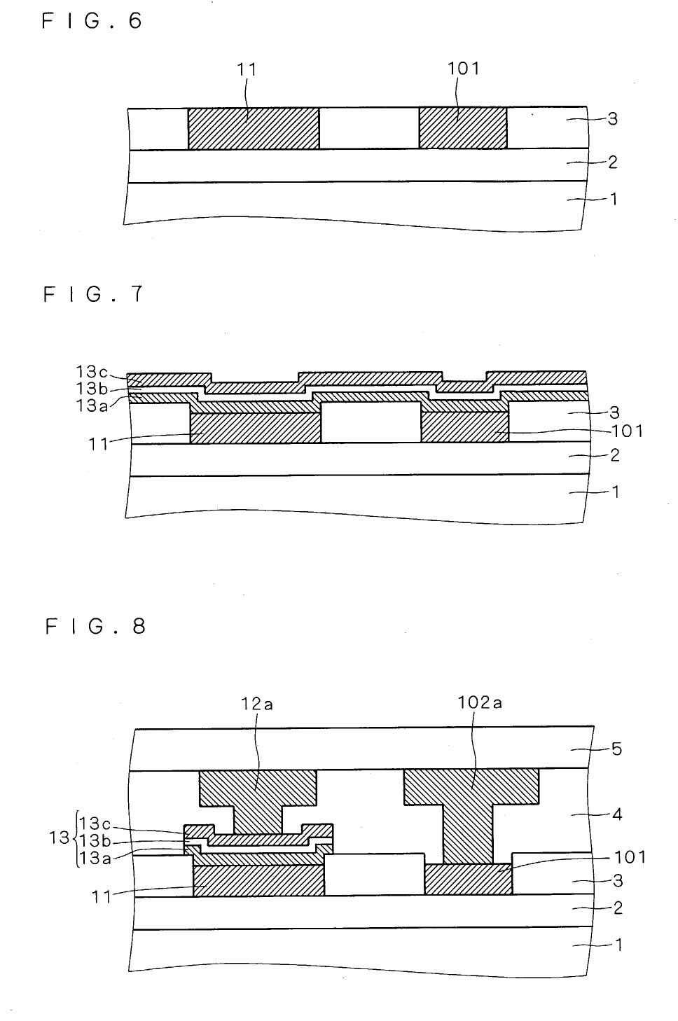

Next, the steps of manufacturing the semiconductor device according to the second preferred embodiment will be described. First, following the same manufacturing steps as those in the first preferred embodiment, the first interlayer insulating film 2, the second interlayer insulating film 3, and the first interconnect lines 11 and 101 are provided over the silicon substrate 1. As copper is used as a material for forming the first interconnect lines 11 and 101, the damascene process is employed. The upper surfaces of the resultant first interconnect lines 11 and 101, and of the second interlayer insulating film 3 are thus flat as shown in FIG. 6.

Etching selectivity can be defined between the first interconnect lines 11 and 101, and the second interlayer insulating film 3. Therefore, using the process such as wet etching for selectively etching the first interconnect lines 11 and 101, the upper surfaces of the first interconnect lines 11 and 101, and of the second interlayer insulating film 3 are etched, so that the first interconnect lines 11 and 101 are etched to a greater depth. As a result, the upper surfaces of the first interconnect lines 11 and 101 are lower in height than the second interlayer insulating film 3. Difference in height between the upper surfaces of the second interlayer insulating film 3, and of the first interconnect lines 11 and 101, namely, difference in level therebetween, is preferably 50 nm or more.

Next, following the same process as that in the first preferred embodiment, a three-layered film for constituting the MIM capacitor (including the high melting point metal films 13a and 13c, and the dielectric film 13b) is deposited on the upper surfaces of the first interconnect lines 11 and 101, and of the second interlayer insulating film 3. The upper surface of the second interlayer insulating film 3 has different height from those of the first interconnect lines 11 and 101. Therefore, the upper surface of the three-layered film provided thereon includes differences in level generated at the positions corresponding to those of the first interconnect lines 11 and 101 as shown in FIG. 7.

The three-layered film is then patterned by dry etching, to form the MIM capacitor 13 on the first interconnect line 11. During lithography process for this patterning, the positions of the differences in level of the three-layered film can be optically detected. As these differences are defined at the positions corresponding to those of the first interconnect lines 11 and 101, the positions of the differences can be used for detecting the position of the first interconnect line 11. It is thus possible to perform precise alignment between the MIM capacitor 13 and the first interconnect line 11.

As a result, the MIM capacitor 13 formed by patterning of the three-layered film can be precisely on the first interconnect line 11. That is, misalignment of the MIM capacitor 13 with the first interconnect line 11 is avoided, whereby characteristic deterioration of the semiconductor device such as deterioration in operational reliability may be suppressed.

Thereafter, following the same processes as those in the first preferred embodiment, the third interlayer insulating film 4, and the second interconnect lines 12 and 102 are provided. Last, the passivation film 5 is provided to cover the third interlayer insulating film 4, and the second interconnect lines 12 and 102. The resultant semiconductor device is as given in FIG. 5.

In the second preferred embodiment, the second interconnect lines 12 and 102 may also be copper lines. FIG. 8 illustrates the structure in which the second interconnect lines are made of copper. Following the damascene process (dual damascene or single damascene process), the second interconnect lines 12a and 102a are formed using copper.

Third Preferred Embodiment

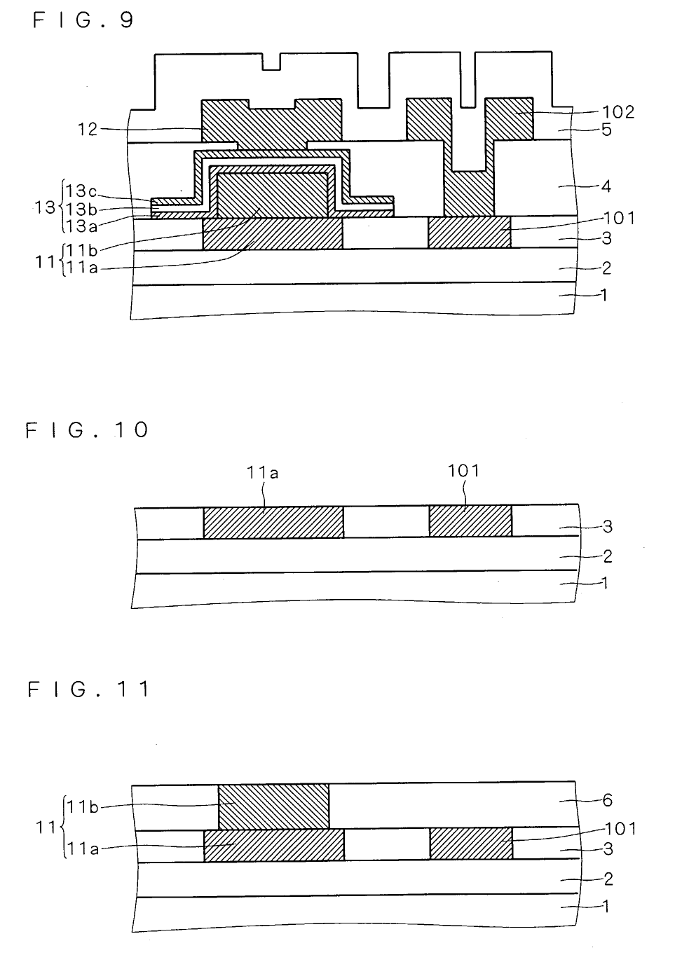

FIG. 9 illustrates the structure of a semiconductor device according to the third preferred embodiment of the present invention. In FIG. 9, the same device elements as those in FIG. 21 are designated by the same reference numerals. The first interconnect lines 11 and 101 are copper lines, and the second interconnect lines 12 and 102 are aluminum lines.

As shown in FIG. 9, the first interconnect line 11 has a two-layered structure including a first layer 11a provided in the second interlayer insulating film 3, and a second layer 11b provided on the first layer 11a. Namely, the first layer 11a is below the height of the upper surface of the second interlayer insulating film 3, and the second layer 11b is above the height of the upper surface of the second interlayer insulating film 3. The upper surface of the first interconnect line 11 thus reaches a height greater than that of the second interlayer insulating film 3. That is, the upper surfaces of the first interconnect line 11 and the second interlayer insulating film 3 are different in height.

Next, the steps of manufacturing the semiconductor device according to the third preferred embodiment will be described. First, the first interlayer insulating film 2, the second interlayer insulating film 3, the first layer 11a of the first interconnect line 11, and the first interconnect line 101 are provided over the silicon substrate 1. The first layer 11a and the first interconnect line 101 are formed by the damascene process. The upper surfaces of the resultant first layer 11a of the first interconnect line 11, of the first interconnect line 101, and of the second interlayer insulating film 3 are flat as shown in FIG. 10.

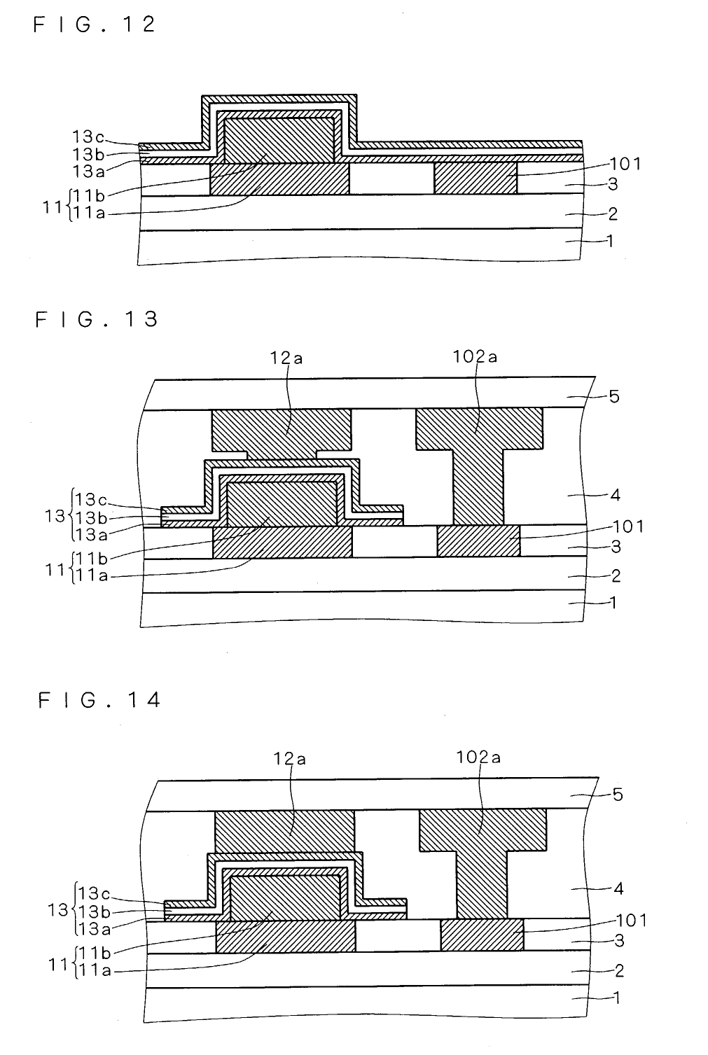

Thereafter, a dummy insulating film 6 is provided on the first layer 11a of the first interconnect line 11, on the first interconnect line 101, and on the second interlayer insulating film 3. Following this, using the damascene process, the second layer 11b is provided in the dummy insulating film 6 to be arranged on the first layer 11a. The resultant first interconnect line 11 having a two-layered structure is as given in FIG. 11. Difference in height between the upper surfaces of the second interlayer insulating film 3 and of the first interconnect line 11, namely, the thickness of the second layer 11b, is preferably 50 nm or more.

Next, the dummy insulating film 6 is removed by dry etching. Thereafter, a three-layered film for constituting the MIM capacitor 13 (including the high melting point metal films 13a and 13c, and the dielectric film 13b) is deposited on the upper surfaces of the first interconnect lines 11 and 101, and of the second interlayer insulating film 3. The upper surface of the second interlayer insulating film 3 has different height from that of the first interconnect line 11. Therefore, the upper surface of the three-layered film provided thereon includes difference in level generated at the position corresponding to that of the first interconnect line 11 as shown in FIG. 12.

The three-layered film is then patterned by dry etching, to form the MIM capacitor 13 on the first interconnect line 11. During lithography process for this patterning, the position of the difference in level of the three-layered film can be optically detected. As this difference is defined at the position corresponding to that of the first interconnect line 11, the position of the difference can be used for detecting the position of the first interconnect line 11. It is thus possible to perform precise alignment between the MIM capacitor 13 and the first interconnect line 11.

As a result, the MIM capacitor 13 formed by patterning of the three-layered film can be precisely on the first interconnect line 11. That is, misalignment of the MIM capacitor 13 with the first interconnect line 11 is avoided, whereby characteristic deterioration of the semiconductor device such as deterioration in operational reliability may be suppressed.

Thereafter, following the same processes as those in the first preferred embodiment, the third interlayer insulating film 4, and the second interconnect lines 12 and 102 are provided. Last, the passivation film 5 is provided to cover the third interlayer insulating film 4, and the second interconnect lines 12 and 102. The resultant semiconductor device is as given in FIG. 9.

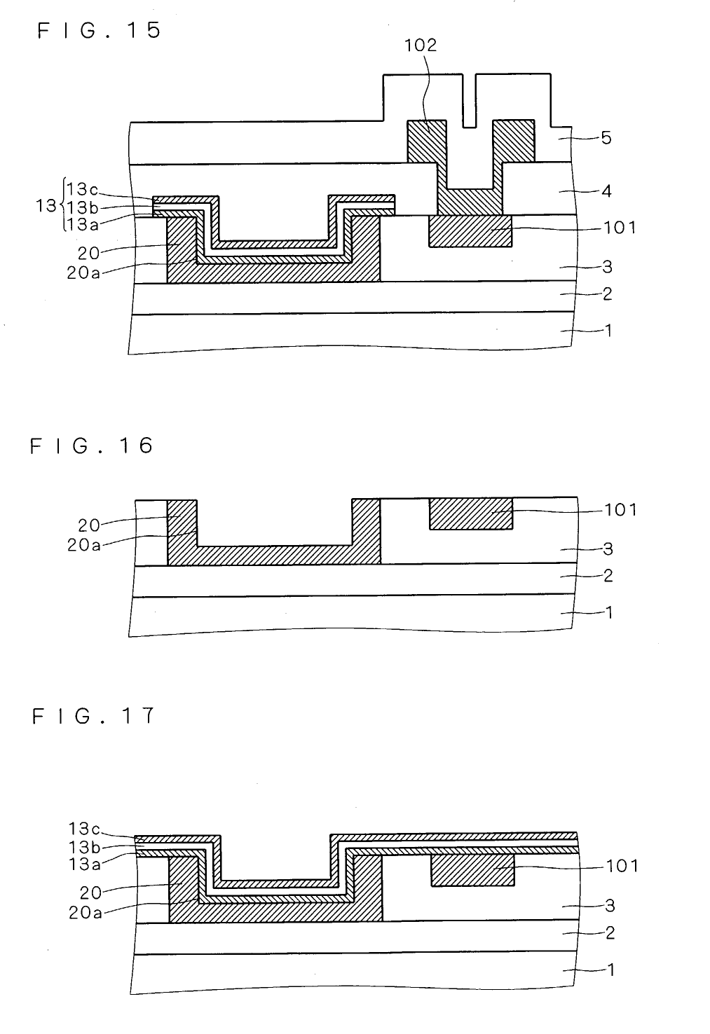

In the third preferred embodiment, the second interconnect lines 12 and 102 may also be copper lines. FIGS. 13 and 14 each illustrate the structure in which the second interconnect lines are made of copper. Following the damascene process, the second interconnect lines 12a and 102a are formed using copper. More particularly, the structure obtained by the dual damascene process for both the second interconnect lines 12a and 102a is shown in FIG. 13. The structure obtained by the single damascene process for the second interconnect line 12a, and by the dual damascene process for the second interconnect line 102a, is shown in FIG. 14.

When both the second interconnect lines 12a and 102a are to be formed by the dual damascene process, the following problem may be caused. That is, as the upper surface of the first interconnect line 101 and that of the MIM capacitor 13 are considerably different in height, the upper surface of the MIM capacitor 13 may be unnecessarily etched during the etching process for defining contact holes. In contrast, when the second interconnect line 12a is to be formed by the single damascene process, namely, when only an interconnect trench is defined for the second interconnect line 12a, no etching process for a contact hole is required. As a result, the unnecessary etching of the upper surface of the MIM capacitor 13 can be avoided.

Fourth Preferred Embodiment

FIG. 15 illustrates the structure of a semiconductor device according to the fourth preferred embodiment of the present invention. More particularly, in the semiconductor device including an MIM capacitor that uses an interconnect line as a lower electrode thereof, a part provided with an alignment mark is illustrated in cross section. In FIG. 15, the same device elements as those in FIG. 21 are designated by the same reference numerals. As shown in FIG. 15, an alignment mark 20 has a recessed portion 20a defined on the upper surface thereof. Further, the alignment mark 20 and the first interconnect line 101 are made of copper, and the second interconnect line 102 is an aluminum line.

Next, the steps of manufacturing the semiconductor device according to the fourth preferred embodiment will be described. First, by the combination of processes including CVD, etchback, CMP and the like, the first interlayer insulating film 2 and the second interlayer insulating film 3 are provided over the silicon substrate 1. Following this, trenches for forming the alignment mark 20, for the first interconnect line 101, and for a lower electrode (first interconnect line) that is not shown, are defined in the second interlayer insulating film 3 by photolithography and dry etching. The depth of the trench for the alignment mark 20 should be greater than that for the first interconnect line 101.

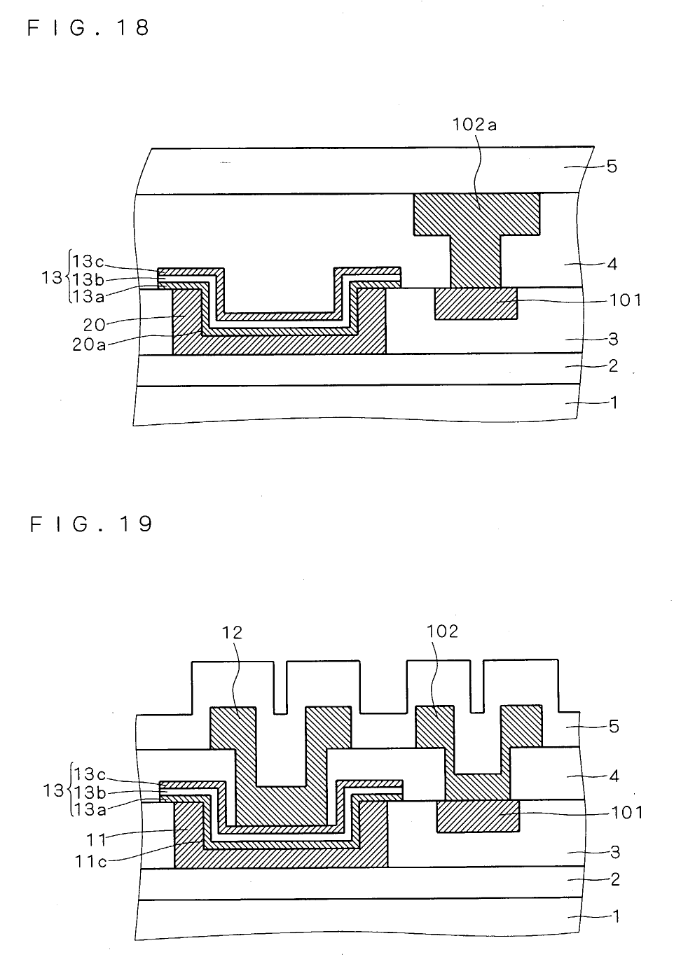

Thereafter, a barrier film against copper is deposited on the second interlayer insulating film 3, followed by deposition of copper by plating or CVD. The amount of copper to deposited is so controlled that the trench for the alignment mark 20 is not completely filled. Then the excess copper and the barrier film on the upper surface of the second interlayer insulating film 3 are removed by polishing using CMP, whereby the alignment mark 20, the first interconnect line 101, and the lower electrode (not shown) are formed in the trenches. As the amount of copper to be deposited is so controlled that the trench for the alignment mark 20 is not completely filled as described, the recessed portion 20a is defined on the upper surface of the alignment mark 20 as shown in FIG. 16.

Next, a three-layered film for constituting the MIM capacitor 13 (including the high melting point metal films 13a and 13c, and the dielectric film 13b) is provided on the upper surfaces of the alignment mark 20, of the first interconnect line 101, and of the second interlayer insulating film 3. More particularly, the high melting point metal film 13a, the dielectric film 13b, and the high melting point metal film 13c are provided in this order. The recessed portion 20a is defined on the upper surface of the alignment mark 20. Therefore, the upper surface of the three-layered film provided thereon includes difference in level generated at the position corresponding to that of the alignment mark 20.

Subsequent to this, the three-layered film is patterned by dry etching, to remove the three-layered film on the first interconnect line 101. The three-layered film is further patterned into a predetermined pattern, to form an MIM capacitor (not shown) on the lower electrode (not shown). During lithography process for this patterning, the position of the difference in level of the three-layered film can be optically detected. As this difference is defined at the position corresponding to that of the alignment mark 20, the position of the difference can be used for detecting the position of the alignment mark 20. It is thus possible to perform precise alignment between the MIM capacitor formed by patterning of the three-layered film and the lower electrode thereof.

As a result, the MIM capacitor can be precisely on its lower electrode. That is, misalignment of the MIM capacitor with the lower electrode is avoided, whereby characteristic deterioration of the semiconductor device such as deterioration in operational reliability may be suppressed.

Thereafter, following the same processes as those in the background art, the third interlayer insulating film 4 is provided, and the contact hole is defined over the first interconnect line 101. An aluminum film is thereafter deposited in the contact hole and on the third interlayer insulating film, and is patterned. The second interconnect line 102 is thereby formed. Last, the passivation film 5 is provided. The resultant semiconductor device is as given in FIG. 15.

In the fourth preferred embodiment, the second interconnect line 102 may also be a copper line. FIG. 18 illustrates the structure in which the second interconnect line is made of copper. Following the damascene process (dual damascene or single damascene process), the second interconnect line 102a is formed using copper.

Fifth Preferred Embodiment

The alignment mark 20 discussed in the fourth preferred embodiment may be further applicable as the first interconnect line 11, namely, as the lower electrode of the MIM capacitor 13. In other words, the first interconnect line 11 itself may be operative to serve as an alignment mark.

FIG. 19 illustrates the structure of a semiconductor device according to the fifth preferred embodiment of the present invention. In FIG. 19, the same device elements as those in FIG. 21 are designated by the same reference numerals. The first interconnect lines 11 and 101 are copper lines, and the second interconnect lines 12 and 102 are aluminum lines. In the fifth preferred embodiment, the first interconnect line 11 also serves as an alignment mark. Further, a recessed portion 11c is defined on the upper surface of the first interconnect line 11.

Next, the steps of manufacturing the semiconductor device according to the fifth preferred embodiment will be described. First, the first interlayer insulating film 2 and the second interlayer insulating film 3 are provided over the silicon substrate 1. Thereafter using the damascene process, the first interconnect lines 11 and 101 are formed in the second interlayer insulating film 3. The depth of the trench for forming the first interconnect line 11 should be greater than that for the first interconnect line 101. Further, the amount of copper to be deposited is so controlled that the trench for the first interconnect line 11 is not completely filled. As a result, the first interconnect line 11 provided with the recessed portion 11c defined on the upper surface thereof is formed.

Next, following the same processes as those in the first preferred embodiment, a three-layered film for constituting the MIM capacitor 13 (including the high melting point metal films 13a and 13c, and the dielectric film 13b) is provided on the upper surfaces of the first interconnect lines 11 and 101, and of the second interlayer insulating film 3. The recessed portion 11c is defined on the upper surface of the first interconnect line 11. Therefore, the upper surface of the three-layered film provided thereon includes difference in level generated at the position corresponding to that of the first interconnect line 11.

Subsequent to this, the three-layered film is patterned by dry etching, to form the MIM capacitor 13 on the first interconnect line 11. The upper surface of the three-layered film includes difference in level generated at the position corresponding to that of the first interconnect line 11. During lithography process for this patterning, it is thus possible to detect the position of the first interconnect line 11 (namely, the position of the alignment mark) using the position of this difference. Therefore, alignment between the MIM capacitor 13 and the first interconnect line 11 can be precisely performed.

As a result, the MIM capacitor 13 formed by patterning of the three-layered film can be precisely on the first interconnect line 11. That is, misalignment of the MIM capacitor 13 with the first interconnect line 11 is avoided, whereby characteristic deterioration of the semiconductor device such as deterioration in operational reliability may be suppressed.

Thereafter, following the same processes as those in the first preferred embodiment, the third interlayer insulating film 4, and the second interconnect lines 12 and 102 are provided. Last, the passivation film 5 is provided to cover the third interlayer insulating film 4, and the second interconnect lines 12 and 102. The resultant semiconductor device is as given in FIG. 19.

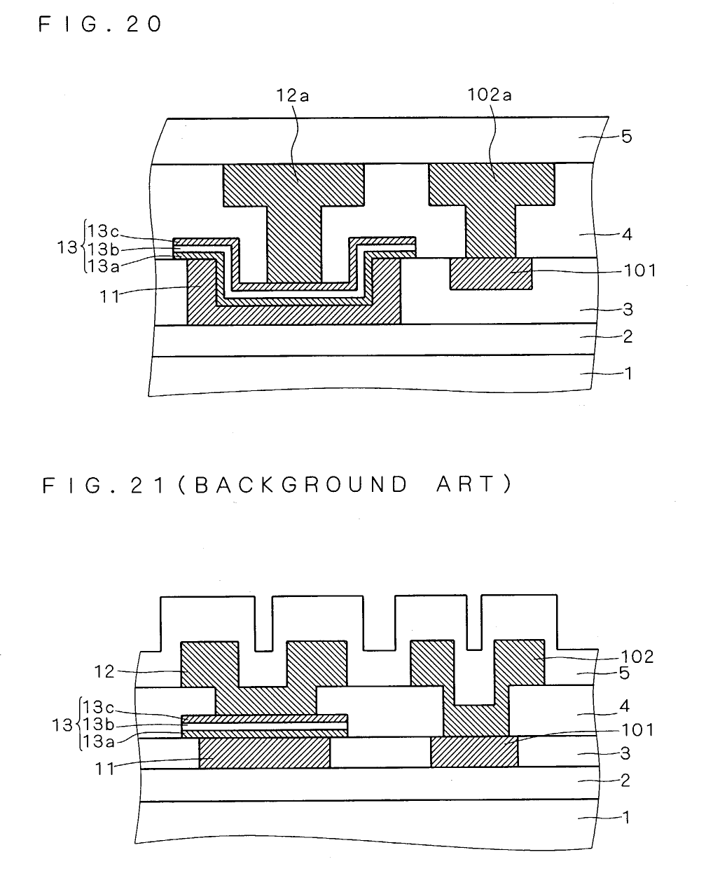

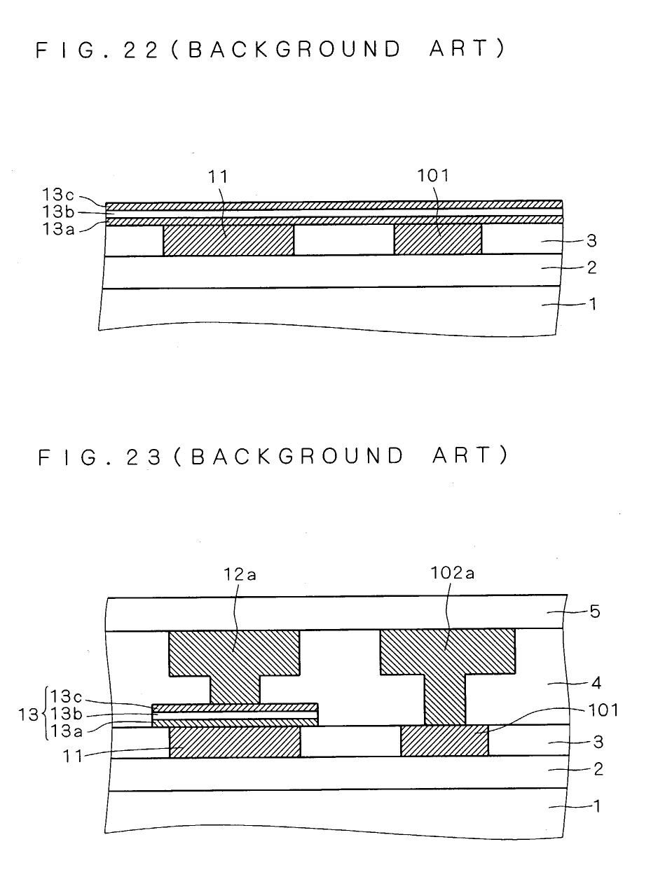

In the fifth preferred embodiment, the second interconnect lines 12 and 102 may also be copper lines. FIG. 20 illustrates the structure in which the second interconnect lines are made of copper. Following the damascene process (dual damascene or single damascene process), the second interconnect lines 12a and 102a are formed using copper.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
an interlayer insulating film provided over a semiconductor substrate, said interlayer insulating film having an upper surface at a constant height;
an interconnect line provided in said interlayer insulating film; and
a capacitor provided on said interconnect line, said capacitor using said interconnect line as a lower electrode thereof, wherein
upper surfaces of said interconnect line and of said interlayer insulating film are different in height.

2. The semiconductor device according to claim 1, wherein
said upper surface of said interconnect line is greater in height than said upper surface of said interlayer insulating film,
said interconnect line has a two-layered structure including a first layer and a second layer,
said first layer is below a height of said upper surface of said interlayer insulating film, and
said second layer is above said height of said upper surface of said interlayer insulating film.

3. The semiconductor device according to claim 1, wherein
difference in height between said upper surface of said interconnect line and said upper surface of said interlayer insulating film is 50 nm or more.

4. The semiconductor device according to claim 1, wherein
said interconnect line is made of copper.

5. A semiconductor device, comprising:
an interlayer insulating film provided over a semiconductor substrate;
an interconnect line provided in said interlayer insulating film; and
a capacitor provided on said interconnect line, said capacitor using said interconnect line as a lower electrode thereof, wherein
a recessed portion is defined on an upper surface of said interconnect line.

6. The semiconductor device according to claim 5, wherein
a depth of said recessed portion is 50 nm or more.

7. The semiconductor device according to claim 5, wherein
said interconnect line is made of copper.

8. A semiconductor device, comprising:
an interlayer insulating film provided over a semiconductor substrate;
an interconnect line and an alignment mark provided in said interlayer insulating film, said interconnect line and said alignment mark being made of the same material; and
a capacitor provided on said interconnect line, said capacitor using said interconnect line as a lower electrode thereof, wherein
a recessed portion is defined on an upper surface of said alignment mark.

9. The semiconductor device according to claim 8, wherein
a depth of said recessed portion is 50 nm or more.

10. The semiconductor device according to claim 8, wherein
said interconnect line is made of copper.
